(19) United States
(12) Patent Application Publication
(10) Pub. No.: US 2026/0297380 A1
(43) Pub. Date: Oct. 1, 2026

(54) CMP POLISHING LIQUID AND POLISHING METHOD

(71) Applicant: Resonac Corporation, Tokyo (JP)

(72) Inventors: Masahiro KANNO, Tokyo (JP); Hiroshi NAKAGAWA, Tokyo (JP)

(73) Assignee: Resonac Corporation, Tokyo (JP)

(21) Appl. No.: 19/477,606

(22) PCT Filed: Dec. 11, 2024
(86) PCT No.: PCT/JP2024/043899

§ 371 Date: Oct. 22, 2025

(30) Foreign Application Priority Data
Dec. 14, 2023 (WO) PCT/JP2023/044912

(51) Int. Cl. C09G 1/02; B24B 37/04; H10P 52/40

(52) U.S. Cl. CPC C09G 1/02; B24B 37/044; H10P 52/407

(57) ABSTRACT

A CMP polishing liquid for polishing a member to be polished that contains a carbon material, wherein the content of abrasive grains is from 0 to 5 mass %, and the CMP polishing liquid contains iron ions. A polishing method including a step of polishing a member to be polished that contains a carbon material using the CMP polishing liquid. A method for manufacturing a semiconductor device, including obtaining a semiconductor device using a member to be polished that has been polished by the polishing method.

### TECHNICAL FIELD

The present disclosure relates to a CMP polishing liquid, a polishing method, and the like.

### BACKGROUND ART

In recent years, electronic devices have become smaller and more sophisticated, and accordingly, demands for higher integration and higher performance of semiconductor integrated circuits (LSIs) have become extremely strict. One of the technologies for achieving higher integration and higher performance of semiconductor integrated circuits (LSIs) is CMP (Chemical Mechanical Polishing) technology. CMP technology is a technique for polishing the surface of a substrate by pressing the substrate against a polishing pad while supplying a polishing liquid between the surface of the substrate and the polishing pad, thereby making the surface of a semiconductor wafer flat and smooth. This technology is particularly important for the planarization of layers formed on a wafer.

In semiconductor integrated circuits (LSIs) aiming for higher integration and higher functionality, the use of carbon materials (e.g., polyimide resins) with excellent properties such as electrical insulation, heat resistance, and mechanical strength is increasing. Carbon materials are used as insulating layers between different metal layers and between wirings, but due to their high hardness and chemical resistance, it is required that they can be efficiently removed by CMP. Patent Literature 1 describes a polishing composition that contains at least one type of abrasive grains having a modified Mohs hardness of 13 or more, as a polishing liquid capable of polishing a polyimide film in a short time, maintaining high flatness, and suppressing the occurrence of polishing scratches.

### CITATION LIST

### Patent Literature

Patent Literature 1: Japanese National Phase PCT Patent Publication No. 2010-135472

### SUMMARY OF INVENTION

### Technical Problem

When polishing a carbon material having a thickness of 10 μm or more, the polishing may be divided into a rough polishing step of polishing the carbon material at a high polishing rate and a finish polishing step of polishing at a lower polishing rate than the rough polishing step to adjust the carbon material to an appropriate thickness. In the finish step, if the carbon material is polished at a high polishing rate using abrasive grains, not only are polishing scratches more likely to occur on the surface of the carbon material, but defects on the wafer due to abrasive grain residues may also occur. On the other hand, in conventional polishing liquids, if the content of abrasive grains is reduced too much, it has been difficult to polish the carbon material at a sufficient polishing rate.

Therefore, an aspect of the present disclosure aims to provide a CMP polishing liquid that can polish a carbon material at an excellent polishing rate, in a polishing liquid that does not contain abrasive grains or has a low content of abrasive grains (for example, 5 mass % or less based on the total mass of the polishing liquid). Another aspect of the present disclosure aims to provide a polishing method using such a CMP polishing liquid.

### Solution to Problem

The present disclosure includes, for example, the following [1] to [19].

[1] A CMP polishing liquid for polishing a member to be polished that contains a carbon material, wherein the content of abrasive grains is from 0 to 5 mass %, wherein the CMP polishing liquid contains iron ions.
[2] The CMP polishing liquid according to [1], wherein the content of the iron ions is from 0.001 to 0.2 mass %.
[3] The CMP polishing liquid according to [1] or [2], wherein the content of the abrasive grains is from 0 to 0.01 mass %.
[4] The CMP polishing liquid according to any one of [1] to [3], wherein the abrasive grains include particles having an old Mohs hardness of less than 8.
[5] The CMP polishing liquid according to any one of [1] to [4], wherein the abrasive grains include silica particles.
[6] The CMP polishing liquid according to any one of [1] to [5], wherein a mass ratio of the content of the abrasive grains to the content of the iron ions is from 0 to 500.
[7] The CMP polishing liquid according to any one of [1] to [6], further containing an oxidizing agent.
[8] The CMP polishing liquid according to [7], wherein the oxidizing agent includes a peroxide.
[9] The CMP polishing liquid according to any one of [1] to [8], further containing an organic acid component.
[10] The CMP polishing liquid according to [9], wherein the organic acid component includes an amino acid component.
[11] The CMP polishing liquid according to [9] or [10], wherein the content of the organic acid component is from 0.1 to 5 mass %.
[12] The CMP polishing liquid according to any one of [1] to [11], further containing an organic solvent.
[13] The CMP polishing liquid according to [12], wherein the organic solvent includes 3-methoxy-3-methyl-1-butanol.
[14] The CMP polishing liquid according to any one of [1] to [13], wherein the pH is from 1.0 to 7.0.
[15] The CMP polishing liquid according to any one of [1] to [14], wherein the carbon material includes a polyimide resin.
[16] The CMP polishing liquid according to any one of [1] to [15], wherein the member to be polished further contains a metal material.
[17] The CMP polishing liquid according to [16], wherein the metal material includes at least one selected from the group consisting of copper, copper alloy, copper oxide, and copper alloy oxide.
[18] A polishing method, including a step of polishing a member to be polished that contains a carbon material using the CMP polishing liquid according to any one of [1] to [17].
[19] A method for manufacturing a semiconductor device, including obtaining a semiconductor device using a member to be polished that has been polished by the polishing method according to [18].

### Advantageous Effects of Invention

According to an aspect of the present disclosure, it is possible to provide a CMP polishing liquid that can polish a carbon material at an excellent polishing rate, in a polishing liquid that does not contain abrasive grains or has a low content of abrasive grains (for example, 5 mass % or less based on the total mass of the polishing liquid). According to another aspect of the present disclosure, it is possible to provide a polishing method using such a CMP polishing liquid.

### DESCRIPTION OF EMBODIMENTS

Hereinafter, embodiments of the present disclosure will be described.

In this specification, a numerical range indicated using “to” indicates a range including the numerical values described before and after “to” as the minimum value and the maximum value, respectively. “A or more” in a numerical range means a range of A and more than A. “A or less” in a numerical range means a range of A and less than A. In the numerical ranges described in stages in this specification, the upper limit value or lower limit value of a numerical range in one stage can be arbitrarily combined with the upper limit value or lower limit value of a numerical range in another stage. In the numerical ranges described in this specification, the upper limit value or lower limit value of the numerical range may be replaced with a value shown in the examples. “A or B” means that either A or B may be included, and both may be included. Unless otherwise specified, the materials exemplified in this specification can be used alone as one type or in combination of two or more types. The content of each component in a composition means the total amount of the plurality of substances corresponding to each component present in the composition, unless otherwise specified. The term “step” is included in this term as long as the intended action of the step is achieved, even if it is not a stand-alone step and cannot be clearly distinguished from other steps.

The CMP polishing liquid according to the present embodiment (hereinafter, also simply referred to as “polishing liquid”) is a polishing liquid for polishing a carbon material (polishing liquid for a carbon material), and can be used for polishing a surface to be polished that includes a carbon material. A carbon material is a carbon-containing material that includes carbon atoms. As the carbon material, a material in which carbon atoms account for ⅓ or more based on all atoms constituting the carbon material (the content of carbon atoms is 33 atm % or more based on the total amount of atoms constituting the carbon material) can be used. Examples of the carbon material include resin materials such as polyimide resin, epoxy resin, acrylic resin (a polymer having structural units derived from a monomer having a (meth)acryloyl group), polybenzoxazole resin, and phenol resin; and amorphous carbon (diamond-like carbon (DLC)). The carbon material may include at least one selected from the group consisting of polyiimide resin, epoxy resin, acrylic resin, polybenzoxazole resin, phenol resin, and amorphous carbon. The carbon material can have a carbon-carbon bond. The carbon material may be a photosensitive resin or a non-photosensitive resin (a resin that does not have photosensitivity).

Polyimide resin has excellent electrical insulation properties and can be used as an insulating layer between different metal layers and between wirings. As a method for forming a film of polyimide resin, a method of forming a thin film by spin coating, dip coating, spray coating, or the like of a polyimide solution, and forming a polyimide resin film by heating and/or light irradiation can be mentioned.

The polishing liquid according to the present embodiment can be used for polishing a surface to be polished that includes a metal material. Examples of the metal material include metals such as copper, nickel, gold, silver, tin, zinc, platinum, bismuth, indium, and antimony, alloys of these metals, oxides of these metals, and oxides of alloys of these metals. The polishing liquid according to the present embodiment may be used for polishing a surface to be polished that includes at least one selected from the group consisting of copper, copper alloy, copper oxide, and copper alloy oxide.

The polishing liquid according to the present embodiment has a content of abrasive grains of 0 to 5 mass % (5 mass % or less) and contains at least iron ions. According to the polishing liquid of the present embodiment, a carbon material can be polished at an excellent polishing rate. According to the polishing liquid of the present embodiment, for example, a polishing rate of a carbon material of 100 nm/min or more can be obtained in the evaluation described in the examples below.

The reason why the effect of being able to polish a carbon material at an excellent polishing rate is obtained is not clear, but the following reason is exemplified. However, the reason why the above-mentioned effect is obtained is not limited to the following content. That is, iron ions modify the carbon material, whereby the molecular chains (carbon-carbon bonds, etc.) of the carbon material are cleaved and the mechanical strength of the carbon material is reduced. Therefore, it is presumed that the carbon material can be polished at an excellent polishing rate even if the content of abrasive grains is low.

The polishing liquid according to the present embodiment can be used, for example, for polishing in a wiring formation step and the like of a semiconductor device. The polishing liquid according to the present embodiment can be suitably used not only for polishing a carbon material used as a constituent material of a hard mask, but also for polishing an interlayer insulating film using a carbon material, and the like. The polishing liquid according to the present embodiment can also be suitably used for polishing a metal material used as a constituent material of a metal wiring, and the like.

The polishing liquid according to the present embodiment contains iron ions. The iron ions may include at least one selected from the group consisting of Fe²⁺ and Fe³⁺, from the viewpoint of easily polishing a carbon material at an excellent polishing rate.

By obtaining a polishing liquid using an iron ion-supplying agent, a polishing liquid containing iron ions can be obtained. The polishing liquid according to the present embodiment may contain an iron ion-supplying agent. The iron ion-supplying agent supplies iron ions into the polishing liquid.

Examples of the iron ion-supplying agent include salts of iron ions, hydrates of such salts, and the like. The salt of iron ions may include at least one selected from the group consisting of inorganic salts and organic salts. Examples of the inorganic salt include iron nitrate, iron sulfate, iron boride, iron chloride, iron bromide, iron iodide, iron phosphate, iron fluoride, and the like. Examples of the organic salt include iron(III) formate, iron(II) formate, iron acetate, iron propionate, iron oxalate, iron malonate, iron succinate, iron malate, iron glutarate, iron tartrate, iron lactate, iron citrate, and the like. The salt of iron ions (inorganic salt, organic salt, etc.) may include a ligand such as ammonium or water.

In a polishing liquid containing an iron ion-supplying agent, the iron ion-supplying agent may exist in a state of being dissociated into iron ions and an anion derived from the iron ion-supplying agent. The polishing liquid according to the present embodiment may contain at least one selected from the group consisting of nitrate ions and acetate ions, from the viewpoint of easily polishing a carbon material at an excellent polishing rate. The polishing liquid according to the present embodiment may contain at least one selected from the group consisting of iron nitrate, a hydrate of iron nitrate, and iron acetate, from the viewpoints of easily polishing a carbon material at an excellent polishing rate, relatively little contamination of a polishing apparatus, a substrate, etc., and being inexpensive and easily available.

The content of iron ions may be in the following range based on the total mass of the polishing liquid. The content of iron ions may be 0.0001 mass % or more, 0.0005 mass % or more, 0.001 mass % or more, 0.0012 mass % or more, 0.0014 mass % or more, 0.002 mass % or more, 0.003 mass % or more, 0.004 mass % or more, 0.005 mass % or more, 0.0055 mass % or more, 0.006 mass % or more, 0.007 mass % or more, 0.008 mass % or more, 0.009 mass % or more, 0.01 mass % or more, exceeding 0.01 mass %, 0.011 mass % or more, 0.02 mass % or more, 0.03 mass % or more, 0.04 mass % or more, 0.05 mass % or more, 0.06 mass % or more, 0.07 mass % or more, 0.08 mass % or more, 0.09 mass % or more, 0.1 mass % or more, exceeding 0.1 mass %, or 0.11 mass % or more, from the viewpoint of easily polishing a carbon material at an excellent polishing rate. The content of iron ions may be 10 mass % or less, 8 mass % or less, 6 mass % or less, 5 mass % or less, 4 mass % or less, 3 mass % or less, 2 mass % or less, 1 mass % or less, less than 1 mass %, 0.9 mass % or less, 0.8 mass % or less, 0.7 mass % or less, 0.6 mass % or less, 0.5 mass % or less, 0.4 mass % or less, 0.3 mass % or less, 0.2 mass % or less, 0.15 mass % or less, 0.12 mass % or less, 0.1 mass % or less, less than 0.1 mass %, 0.09 mass % or less, 0.08 mass % or less, 0.07 mass % or less, 0.06 mass % or less, 0.05 mass % or less, 0.04 mass % or less, 0.03 mass % or less, 0.02 mass % or less, 0.015 mass % or less, 0.012 mass % or less, 0.01 mass % or less, or less than 0.01 mass %. From these viewpoints, the content of iron ions may be from 0.0001 to 10 mass %, from 0.0001 to 5 mass %, from 0.0001 to 1 mass %, from 0.0005 to 0.5 mass %, from 0.001 to 0.2 mass %, or from 0.0014 to 0.12 mass %. The content of the iron ion-supplying agent may be adjusted so that the content of iron ions in the polishing liquid falls within the above-mentioned respective ranges. When converting the content of iron ions (unit: mass %) to a content (unit: mM), 1 may be adopted as the specific gravity of the polishing liquid. When the content of iron ions is from 0.001 to 10 mass %, the content of iron ions can be converted to 0.018 to 179 mM.

The polishing liquid according to the present embodiment contains abrasive grains as an optional component. That is, the polishing liquid may contain abrasive grains or may not contain abrasive grains.

Examples of the abrasive grains include silica particles, cerium oxide (ceria) particles, cerium hydroxide particles, aluminum oxide (alumina) particles, silicon nitride particles, zirconium oxide (zirconia: yttria-added zirconia particles, etc.) particles, titanium oxide (titania) particles, yttrium oxide (yttria) particles, silicon carbide particles, diamond particles, polymer particles, and the like. The abrasive grains may include particles having an old Mohs hardness of less than 8, may include particles having an old Mohs hardness of 5 or more and less than 8, may include particles having an old Mohs hardness of 5 to 7, may include particles having an old Mohs hardness of 6 to 7, and may include at least one selected from the group consisting of silica particles and cerium oxide particles, from the viewpoints of easily polishing a carbon material and a metal material at an excellent polishing rate, and of making it difficult for defects such as scratches to occur on the polished surface of the object to be polished and easily improving the flatness of the surface to be polished. The old Mohs hardness means a value measured using a Molis hardness tester on a bulk body having the same composition as the abrasive grains.

When silica particles are included as the abrasive grains, examples of the silica particles include colloidal silica, amorphous silica, crystalline silica, fused silica, spherical silica, synthetic silica, hollow silica, and the like. When the polishing liquid contains abrasive grains, it may include colloidal silica as the abrasive grains, from the viewpoints of easily polishing a carbon material and a metal material at an excellent polishing rate, and of making it difficult for defects such as scratches to occur on the polished surface of the object to be polished and easily improving the flatness of the surface to be polished.

The average particle size of the abrasive grains may be 10 nm or more, 15 nm or more, 20 nm or more, 25 nm or more, 30 nm or more, 35 inn or more, 40 nm or more, 45 nm or more, 50 nm or more, 55 nm or more, or 60 nm or more, from the viewpoint that the physical polishing ability per abrasive grain is easily sufficiently secured, and thus a carbon material and a metal material are easily polished at an excellent polishing rate. The average particle size of the abrasive grains may be 1000 nm or less, 800 nm or less, 600 nm or less, 400 nm or less, 300 nm or less, 200 nm or less, 190 nm or less, 180 nm or less, 150 nm or less, 120 nm or less, 100 nm or less, 80 nm, or less, or 70 nm or less, from the viewpoint that the number of abrasive grains per unit area in contact with the surface to be polished is easily sufficiently secured, and thus a carbon material and a metal material are easily polished at an excellent polishing rate. From these viewpoints, the average particle size of the abrasive grains may be from 10 to 1000 mu, from 10 to 600 mu, from 10 to 200 nm, from 10 to 100 nm, from 10 to 80 nm, from 15 to 190 nm, from 20 to 180 nm, from 30 to 100 nm, from 30 to 200 urn, from 30 to 80 urn, from 50 to 200 nm, from 50 to 100 nm, or from 50 to 80 nm.

The “average particle size” is the secondary particle size of the abrasive grains, and can be obtained by measuring the particle size of the abrasive grains in the polishing liquid or the particle size of the abrasive grains before being blended into the polishing liquid. The average particle size can be measured by a light diffraction/scattering particle size distribution analyzer, and may be measured by preparing a sample in which the abrasive grains are dispersed in water. For example, using a COULTER N4SD manufactured by COULTER Electronics, measurement can be performed under the conditions of a measurement temperature of 20° C., a solvent refractive index of 1.333 (water), a particle refractive index of Unknown (setting), a solvent viscosity of 1.005 cp (water), a Run Time of 200 seconds, a laser incident angle of 90°, and an Intensity (scattering intensity, corresponding to turbidity) of 5E+04 to 4E+05, and if the Intensity is higher than 4E+05, it can be measured after diluting with water. Since colloidal particles are usually obtained in a state of being dispersed in water, they can also be measured by appropriately diluting them so as to fall within the above-mentioned range of scattering intensity.

The content of silica particles in the abrasive grains may be 50 mass % or more, exceeding 50 mass %, 60 mass % or more, 70 mass % or more, 80 mass % or more, 90 mass % or more, 95 mass % or more, 98 mass % or more, or 99 mass % or more, based on the total mass of the abrasive grains (the entire abrasive grains included in the polishing liquid), from the viewpoint of easily polishing a carbon material and a metal material at an excellent polishing rate. The abrasive grains may be an embodiment consisting of silica particles (substantially 100 mass % of the abrasive grains included in the polishing liquid are silica particles).

The polishing liquid according to the present embodiment may not contain aluminum oxide (alumina) particles, and the abrasive grains may not include aluminum oxide (alumina). The content of aluminum oxide (alumina) particles may be 0.01 mass % or less, less than 0.01 mass %, 0.001 mass % or less, or 0.0001 mass % or less, based on the total mass of the polishing liquid.

The polishing liquid according to the present embodiment may not contain zirconia particles, and the abrasive grains may not include zirconia. The content of zirconia particles may be 0.01 mass % or less, less than 0.01 mass %, 0.001 mass % or less, or 0.0001 mass % or less, based on the total mass of the polishing liquid.

The content of the abrasive grains is from 0 to 5 mass % based on the total mass of the polishing liquid. The content of the abrasive grains may be from 0 to 4 mass %, from 0 to 3 mass %, from 0 to 2 mass %, from 0 to 1 mass %, 0 mass % or more and less than 1 mass %, from 0 to 0.5 mass %, from 0 to 0.1 mass %, 0 mass % or more and less than 0.1 mass %, from 0 to 0.05 mass %, from 0 to 0.01 mass %, 0 mass % or more and less than 0.01 mass %, from 0 to 0.005 mass %, from 0 to 0.001 mass %, or 0 mass % or more and less than 0.001 mass %, based on the total mass of the polishing liquid, from the viewpoints that the amount of abrasive grains per unit area of the surface to be polished becomes small, so that iron ions are more likely to preferentially contact the surface to be polished, and the modification of the carbon material is promoted, thereby making it easier to polish the carbon material at an excellent polishing rate, and that the occurrence of scratches is easily suppressed.

The mass ratio of the content of the abrasive grains to the content of the iron ions (content of abrasive grains/content of iron ions) may be from 0 to 500, from 0 to 450, from 0 to 400, from 0 to 350, from 0 to 300, from 0 to 250, from 0 to 200, from 0 to 150, from 0 to 100, from 0 to 50, from 0 to 30, from 0 to 10, from 0 to 5, or from 0 to 1, from the viewpoints that the amount of abrasive grains per unit area of the surface to be polished becomes small, so that iron ions are more likely to preferentially contact the surface to be polished, and the modification of the carbon material is promoted, thereby making it easier to polish the carbon material at an excellent polishing rate, and that the occurrence of scratches is easily suppressed.

The polishing liquid according to the present embodiment may contain an organic acid component. Examples of the organic acid component include organic acids, salts thereof (e.g., alkali metal salts such as sodium salts; alkaline earth metal salts such as calcium salts), and the like. By using an organic acid component, the carbon material and the metal material are further modified, and the polishing rates of the carbon material and the metal material are likely to be improved. Although the effect of improving the polishing rate of the carbon material is not obtained when the organic acid component is used in the absence of iron ions, the polishing rate of the carbon material can be improved when the organic acid component is used in the presence of iron ions.

The polishing liquid according to the present embodiment can contain an oxidizing agent such as hydrogen peroxide, as will be described later. In such a polishing liquid, due to the interaction between iron ions and the oxidizing agent (hydrogen peroxide, etc.), the decomposition of the oxidizing agent may proceed, and the storage stability of the polishing liquid may be impaired. On the other hand, such decomposition of the oxidizing agent can be suppressed by using an organic acid component.

The reason why the above-mentioned effect is obtained by the organic acid component is not clear, but it is presumed that the organic acid component dissociates in the polishing liquid, and the dissociated organic acid component chelates the iron ions, thereby suppressing the decomposition of the oxidizing agent by the iron ions. However, the reason why the above-mentioned effect is obtained is not limited to this content. “Dissociation” means that a cation (e.g., a proton (H⁺)) is released from at least one acid group (e.g., a carboxy group (—COOH)) that the organic acid component has in the polishing liquid, and the acid group exists in the state of an anionic group (e.g., —COO⁻).

The organic acid component may include an organic acid component that does not have a carbon-carbon unsaturated bond, from the viewpoint of easily keeping the oxidizing agent more stable and easily stabilizing the polishing rates of the carbon material and the metal material. The reason why the stability of the oxidizing agent is improved when the organic acid component does not have a carbon-carbon unsaturated bond is not clear, but it is presumed that one reason is that since the reactivity of the carbon-carbon unsaturated bond is relatively high, alteration due to a reaction between the oxidizing agent and the organic acid component in the polishing liquid is less likely to occur when the organic acid component does not have a carbon-carbon unsaturated bond. However, the reason why the above-mentioned effect is obtained is not limited to this content.

Examples of the organic acid include saturated fatty acids such as formic acid, acetic acid, and propionic acid; dicarboxylic acids such as malonic acid, succinic acid, glutaric acid, and adipic acid; hydroxy acids such as malic acid and citric acid; and amino acids to be described later. The organic acid may contain malic acid or may not contain malic acid.

The polishing liquid may contain at least one amino acid component (excluding a compound containing iron ions or a compound corresponding to an oxidizing agent) selected from the group consisting of amino acids and amino acid derivatives, from the viewpoint of easily polishing a carbon material and a metal material at an excellent polishing rate. An amino acid is a compound having both an amino group and a carboxyl group as functional groups. Examples of the amino acid derivative include esters of amino acids, salts of amino acids, peptides, and the like. The amino acid component can be used as a pH adjuster for adjusting the pH of the polishing liquid.

Examples of the amino acid component include glycine, α-alanine, β-alanine (also known as 3-aminopropanoic acid), 2-aminobutyric acid, norvaline, valine, leucine, norleucine, isoleucine, alloisoleucine, phenylalanine, proline, sarcosine, ornithine, lysine, serine, threonine, allothreonine, homoserine, tyrosine, 3,5-diiodo-tyrosine, β-(3,4-dihydroxyphenyl)-alanine, thyroxine, 4-hydroxy-proline, cysteine, methionine, ethionine, lanthionine, cystathionine, cystine, cysteic acid, aspartic acid, glutanmic acid, S-(carboxymethyl)-cysteine, 4-aminobutyric acid, asparagine, glutamine, azaserine, arginine, canavanine, citrulline, δ-hydroxy-lysine, creatine, kynarenine, histidine, 1-methyl-histidine, 3-methyl-histidine, ergothioneine, tryptophan, glycylglycine, glycylglycylglycine, vasopressin, oxytocin, cassinin, eledoisin, glucagon, secretin, proopiomelanocortin, enkephalin, prodynorphin, and the like. The amino acid component may include at least one selected from the group consisting of glycine and β-alanine, from the viewpoint of easily polishing a carbon material and a metal material at an excellent polishing rate.

The content of glycine in the organic acid or amino acid may be 50 mass % or more, exceeding 50 mass %, 60 mass % or more, 70 mass % or more, 80 mass % or more, 90 mass % or more, 95 mass % or more, 98 mass % or more, or 99 mass % or more, based on the total mass of the organic acid (the entire organic acid included in the polishing liquid) or the total mass of the amino acid (the entire amino acid included in the polishing liquid), from the viewpoint of easily polishing a carbon material and a metal material at an excellent polishing rate. The organic acid or amino acid may be an embodiment consisting of glycine (substantially 100 mass % of the organic acid or amino acid included in the polishing liquid is glycine).

The content of the organic acid component may be in the following range based on the total mass of the polishing liquid, from the viewpoint of easily stabilizing the polishing rates of the carbon material and the metal material. The content of the organic acid component may be 0.01 mass % or more, 0.05 mass % or more, 0.1 mass % or more, 0.2 mass % or more, 0.3 mass % or more, 0.5 mass % or more, 1 mass % or more, 1.5 mass % or more, 2 mass % or more, 2.5 mass % or more, or 3 mass % or more. The content of the organic acid component may be 10 mass % or less, 5 mass % or less, 3 mass % or less, 1 mass % or less, 0.8 mass % or less, 0.5 mass % or less, or 0.3 mass % or less. From these viewpoints, the content of the organic acid component may be from 0.01 to 10 mass %, from 0.01 to 5 mass %, from 0.01 to 3 mass %, from 0.05 to 10 mass %, from 0.05 to 5 mass %, from 0.05 to 3 mass %, from 0.1 to 10 mass %, from 0.1 to 5 mass %, or from 0.1 to 3 mass %. The content of the amino acid component may be within the above-mentioned range.

The mass ratio of the content of the organic acid component to the content of the abrasive grains (content of organic acid component/content of abrasive grains) may be in the following range, from the viewpoint of easily polishing a carbon material and a metal material at an excellent polishing rate. The mass ratio may be from 0 to 10, from 0 to 5, from 0 to 2, from 0 to 1.5, from 0 to 1, from 0 to 0.5, from 0 to 0.1, from 0 to 0.05, or from 0 to 0.01. The mass ratio of the content of the amino acid component to the content of the abrasive grains (content of amino acid component/content of abrasive grains) may be within the above-mentioned range.

The mass ratio of the content of the organic acid component to the content of the iron ions (content of organic acid/content of iron ions) may be in the following range, from the viewpoint of easily polishing a carbon material and a metal material at an excellent polishing rate. The mass ratio may be 0.1 or more, 0.5 or more, 1 or more, 2 or more, 10 or more, 50 or more, 100 or more, 150 or more, 200 or more, or 250 or more. The mass ratio may be 3000 or less, 2500 or less, 2200 or less, 2000 or less, 1500 or less, 1000 or less, 800 or less, 600 or less, 500 or less, 400 or less, 350 or less, 300 or less, 250 or less, 200 or less, 150 or less, 100 or less, 50 or less, 30 or less, 20 or less, 10 or less, or 5 or less. From these viewpoints, the mass ratio may be from 0.1 to 3000, from 0.1 to 2000, from 0.1 to 500, from 0.1 to 300, from 0.1 to 100, from 0.1 to 30, from 1 to 3000, from 1 to 2000, from 1 to 500, from 1 to 300, from 1 to 100, from 1 to 30, from 2 to 3000, from 2 to 2000, from 2 to 500, from 2 to 300, from 2 to 100, or from 2 to 30. The mass ratio of the content of the amino acid component to the content of the iron ions (content of amino acid/content of iron ions) may be within the above-mentioned range.

The polishing liquid according to the present embodiment may contain an oxidizing agent (an oxidizing agent for a carbon material; excluding iron ions or a compound corresponding to a compound including iron ions). By using an oxidizing agent, the carbon material and the metal material are further modified, and the polishing rates of the carbon material and the metal material are likely to be improved. Although the effect of improving the polishing rate of the carbon material is not obtained when the oxidizing agent is used in the absence of iron ions, the polishing rate of the carbon material can be improved when the oxidizing agent is used in the presence of iron ions.

Examples of the oxidizing agent include hydrogen peroxide, nitric acid, potassium periodate, hypochlorous acid, ozone water, and the like. When the substrate to be polished is a silicon substrate including integrated circuit elements, the oxidizing agent may include an oxidizing agent that does not include a non-volatile component, and may include hydrogen peroxide, from the viewpoint of avoiding contamination by alkali metals, alkaline earth metals, halides, and the like. The oxidizing agent may include a peroxide, and may include hydrogen peroxide, from the viewpoint of easily polishing a carbon material and a metal material at an excellent polishing rate. As the oxidizing agent, a compound having an oxidation-reduction potential lower than that of iron ions can be used.

The content of the oxidizing agent may be in the following range based on the total mass of the polishing liquid. The content of the oxidizing agent may be 0.1 mass % or more, 0.5 mass % or more, 1 mass % or more, 1.5 mass % or more, 1.7 mass % or more, 2 mass % or more, 2.5 mass % or more, 3 mass % or more, 3.5 mass % or more, or 4 mass % or more, from the viewpoint of easily polishing a carbon material and a metal material at an excellent polishing rate. The content of the oxidizing agent may be 20 mass % or less, 15 mass % or less, 10 mass % or less, 8 mass % or less, 6 mass % or less, 5 mass % or less, 4.5 mass % or less, or 4 mass % or less. From these viewpoints, the content of the oxidizing agent may be from 0.1 to 20 mass %, from 0.1 to 10 mass %, from 0.1 to 5 mass %, from 1 to 20 mass %, from 1 to 10 mass %, from 1 to 5 mass %, from 2 to 20 mass %, from 2 to 10 mass %, from 2 to 5 mass %, from 3 to 10 mass %, or from 3 to 5 mass %.

The mass ratio of the content of the abrasive grains to the content of the oxidizing agent (content of abrasive grains/content of oxidizing agent) may be in the following range, from the viewpoint of easily polishing a carbon material and a metal material at an excellent polishing rate. The mass ratio may be from 0 to 10, from 0 to 5, from 0 to 3, from 0 to 2, from 0 to 1.5, from 0 to 1, from 0 to 0.5, or from 0 to 0.3.

The mass ratio of the content of the oxidizing agent to the content of the iron ions (content of oxidizing agent/content of iron ions) may be in the following range. The mass ratio may be 10 or more, 50 or more, 100 or more, 150 or more, 200 or more, 250 or more, 300 or more, or 350 or more, from the viewpoint of easily polishing a carbon material and a metal material at an excellent polishing rate. The mass ratio may be 3000 or less, 2500 or less, 2000 or less, 1500 or less, 1000 or less, 800 or less, 600 or less, 500 or less, 450 or less, 400 or less, or 370 or less, from the viewpoint of easily polishing a carbon material at an excellent polishing rate. From these viewpoints, the mass ratio may be from 10 to 3000, from 10 to 2000, from 10 to 500, from 100 to 3000, from 100 to 2000, from 100 to 500, from 200 to 3000, from 200 to 2000, from 200 to 500, from 300 to 3000, from 300 to 2000, or from 300 to 500.

The polishing liquid according to the present embodiment may contain an organic solvent (excluding a compound including iron ions, an oxidizing agent, or a compound corresponding to an organic acid component). By using an organic solvent, the polishing rate of a hydrophobic carbon material (for example, a low-dielectric-constant carbon material) may be likely to improve. In addition, by using an organic solvent, decomposition of an oxidizing agent (for example, hydrogen peroxide) is easily suppressed, and thus a carbon material and a metal material are easily polished at an excellent polishing rate.

As the organic solvent, a solvent that is freely miscible with water can be used. Examples of the organic solvent include: carbonic acid esters such as ethylene carbonate, propylene carbonate, dimethyl carbonate, diethyl carbonate, and methyl ethyl carbonate; lactone compounds such as butyrolactone and propiolactone; glycol compounds such as ethylene glycol, propylene glycol, diethylene glycol, dipropylene glycol, triethylene glycol, and tripropylene glycol; as derivatives of glycol compounds, glycol monoethers (for example, glycol monoalkyl ethers) such as ethylene glycol monomethyl ether, propylene glycol monomethyl ether, diethylene glycol monomethyl ether, dipropylene glycol monomethyl ether, triethylene glycol monomethyl ether, tripropylene glycol monomethyl ether, ethylene glycol monoethyl ether, propylene glycol monoethyl ether, diethylene glycol monoethyl ether, dipropylene glycol monoethyl ether, triethylene glycol monoethyl ether, tripropylene glycol monoethyl ether, ethylene glycol monopropyl ether, propylene glycol monopropyl ether, diethylene glycol monopropyl ether, dipropylene glycol monopropyl ether, triethylene glycol monopropyl ether, tripropylene glycol monopropyl ether, ethylene glycol monobutyl ether, propylene glycol monobutyl ether, diethylene glycol monobutyl ether, dipropylene glycol monobutyl ether, triethylene glycol monobutyl ether, and tripropylene glycol monobutyl ether; glycol diethers such as ethylene glycol dimethyl ether, propylene glycol dimethyl ether, diethylene glycol dimethyl ether, dipropylene glycol dimethyl ether, triethylene glycol dimethyl ether, tripropylene glycol dimethyl ether, ethylene glycol diethyl ether, propylene glycol diethyl ether, diethylene glycol diethyl ether, dipropylene glycol diethyl ether, triethylene glycol diethyl ether, tripropylene glycol diethyl ether, ethylene glycol dipropyl ether, propylene glycol dipropyl ether, diethylene glycol dipropyl ether, dipropylene glycol dipropyl ether, triethylene glycol dipropyl ether, tripropylene glycol dipropyl ether, ethylene glycol dibutyl ether, propylene glycol dibutyl ether, diethylene glycol dibutyl ether, dipropylene glycol dibutyl ether, triethylene glycol dibutyl ether, and tripropylene glycol dibutyl ether; ether compounds such as tetrahydrofuran, dioxane, dimethoxyethane, polyethylene oxide, ethylene glycol monomethyl ether acetate, diethylene glycol monoethyl ether acetate, and propylene glycol monomethyl ether acetate; alcohols such as methanol, ethanol, propanol, n-butanol, n-pentanol, n-hexanol, and isopropanol; alkoxy alcohols such as 2-methoxyethanol, 2-ethoxyethanol, 2-(2-methoxy)ethoxyethanol, 2-(2-butoxyethoxy)ethanol, 2-propoxyethanol, 2-butoxyethanol, 3-methoxy-3-methyl-1-butanol, 2-(methoxymethoxy)ethanol, 2-isopropoxyethanol, 2-butoxyethanol, 2-isopentyloxyethanol, 1-propoxy-2-propanol, 3-methoxy-3-methyl-1-butanol, 3-methoxy-1-butanol, 3-methoxy-3-methylbutanol, 1-methoxy-2-butanol, and glycol monoethers; ketones such as acetone and methyl ethyl ketone; phenol; dimethylformamide; N-methylpyrrolidone; ethyl acetate; ethyl lactate; and sulfolane.

The organic solvent may include an alkoxy alcohol, and may include 3-methoxy-3-methyl-1-butanol, from the viewpoint that the polishing rate of a hydrophobic carbon material is likely to improve.

The content of the organic solvent may be in the following range based on the total mass of the polishing liquid. The content of the organic solvent may be 0.1 mass % or more, 0.2 mass % or more, 0.5 mass % or more, 1 mass % or more, 2 mass % or more, 2.5 mass % or more, or 3 mass % or more, from the viewpoint that sufficient wettability of the polishing liquid with respect to the substrate is easily obtained and the polishing rate of a hydrophobic carbon material is likely to improve. The content of the organic solvent may be 95 mass % or less, 50 mass % or less, 30 mass % or less, 10 mass % or less, 8 mass % or less, 6 mass % or less, 5 mass % or less, 4 mass % or less, or 3 mass % or less, from the viewpoints that the polishing rate of a hydrophobic carbon material is likely to improve and that the possibility of ignition is easily reduced. From these viewpoints, the content of the organic solvent may be from 0.1 to 95 mass %, from 0.1 to 50 mass %, from 0.1 to 5 mass %, from 1 to 95 mass %, from 1 to 50 mass %, from 1 to 5 mass %, from 2 to 95 mass %, from 2 to 50 mass %, or from 2 to 5 mass %.

The polishing liquid according to the present embodiment may contain additives other than the above-mentioned components. Examples of such additives include a pH adjuster, a polymer material, and the like.

The polishing liquid according to the present embodiment may contain a basic component as a pH adjuster. Examples of the basic component include sodium hydroxide, ammonia (for example, ammonia water), potassium hydroxide, calcium hydroxide, and the like.

The content of the basic component may be in the following range based on the total mass of the polishing liquid. The content of the basic component may be more than 0 mass %, 0.00001 mass % or more, 0.00005 mass % or more, 0.0001 mass % or more, 0.0005 mass % or more, 0.001 mass % or more, or 0.005 mass % or more. The content of the basic component may be 10 mass % or less, 5 mass % or less, 1 mass % or less, 0.5 mass % or less, 0.1 mass % or less, or 0.05 mass % or less.

The polishing liquid according to the present embodiment may contain water. The content of water in the polishing liquid may be the remainder obtained by subtracting the contents of the other components from the total amount of the polishing liquid. The content of water may be 50 mass % or more, 70 mass % or more, 80 mass % or more, or 90 mass % or more, based on the total mass of the polishing liquid. The polishing liquid according to the present embodiment may be stored as a stock solution for polishing liquid having a lower water content than at the time of polishing. In this case, the polishing liquid can be obtained by diluting the stock solution for polishing liquid with water at the time of polishing.

The pH of the polishing liquid according to the present embodiment may be less than 9.0, 8.5 or less, 8.0 or less, 7.5 or less, 7.0 or less, less than 7.0, 6.5 or less, 6.0 or less, less than 6.0, 5.5 or less, 5.2 or less, 5.0 or less, less than 5.0, 4.8 or less, 4.6 or less, 4.5 or less, 4.4 or less, or 4.3 or less, from the viewpoint of easily polishing a carbon material and a metal material at an excellent polishing rate. The pH of the polishing liquid may be 1.0 or more, 1.2 or more, 1.5 or more, 2.0 or more, more than 2.0, 2.2 or more, 2.4 or more, 2.6 or more, 2.8 or more, 3.0 or more, more than 3.0, 3.2 or more, 3.4 or more, 3.6 or more, 3.8 or more, 4.0 or more, more than 4.0, 4.1 or more, or 4.2 or more, from the viewpoint of easily polishing a carbon material and a metal material at an excellent polishing rate. From these viewpoints, the pH of the polishing liquid may be 1.0 or more and less than 9.0, from 1.0 to 8.0, from 1.0 to 7.0, from 1.0 to 6.0, from 1.0 to 5.0, from 1.0 to 4.5, 2.0 or more and less than 9.0, from 2.0 to 8.0, from 2.0 to 7.0, from 2.0 to 6.0, from 2.0 to 5.0, from 2.0 to 4.5, 3.0 or more and less than 9.0, from 3.0 to 8.0, from 3.0 to 7.0, from 3.0 to 6.0, from 3.0 to 5.0, or from 3.0 to 4.5. The pH of the polishing liquid is defined as the pH at a liquid temperature of 25° C.

The pH of the polishing liquid according to the present embodiment can be measured with a pH meter (for example, trade name: Model (F-51) manufactured by HORIBA, Ltd.). For example, after performing a three-point calibration of the pH meter using a phthalate pH standard solution (pH: 4.01), a neutral phosphate pH standard solution (pH: 6.86), and a borate pH standard solution (pH: 9.18) as calibration solutions, the electrode of the pH meter is placed in the polishing liquid, and the value after stabilization for 2 minutes or more is measured. At this time, the liquid temperature of the calibration solutions and the polishing liquid is 25° C.

The polishing method according to the present embodiment includes a polishing step of polishing a carbon material using the polishing liquid according to the present embodiment. In the polishing step, a surface to be polished including a carbon material may be polished, and a surface to be polished of a material to be polished including a carbon material may be polished, using the polishing liquid according to the present embodiment. In the polishing step, a surface to be polished of a hard mask including a carbon material may be polished using the polishing liquid according to the present embodiment. In the polishing step, a surface to be polished including a metal material may be polished, and a surface to be polished of a material to be polished including a metal material may be polished, using the polishing liquid according to the present embodiment. The polishing liquid used in the polishing step may be a polishing liquid obtained by diluting a stock solution for polishing liquid with water. The surface to be polished may have a layer containing at least one selected from the group consisting of a carbon material and a metal material.

In the polishing step, for example, the surface to be polished of a substrate is pressed against a polishing cloth of a polishing platen, and while a predetermined pressure is applied to the substrate from the surface opposite to the surface to be polished of the substrate (the back surface of the substrate), the polishing liquid according to the present embodiment is supplied between the surface to be polished of the substrate and the polishing cloth, and the substrate is moved relative to the polishing platen, whereby the surface to be polished can be polished.

As the polishing apparatus, for example, when polishing with a polishing cloth, a general polishing apparatus having a holder capable of holding a substrate to be polished and a polishing platen connected to a motor or the like whose rotation speed can be changed and to which a polishing cloth can be attached can be used. As the polishing cloth, a general non-woven fabric, foamed polyurethane, porous fluororesin, or the like can be used, and there is no particular limitation.

There are no limitations on the polishing conditions, but the rotation speed of the polishing platen may be a low rotation of 200 rpm (rpm=min⁻¹) or less so that the substrate does not fly out. The pressure for pressing the substrate having the surface to be polished (such as a semiconductor substrate) against the polishing cloth may be from 1 to 100 kPa, or from 5 to 50 kPa, from the viewpoint of easily satisfying the in-plane uniformity of the polishing rate and the flatness of the pattern. While polishing, the polishing liquid can be continuously supplied to the polishing cloth by a pump or the like. There is no limitation on this supply amount, but the surface of the polishing cloth may be constantly covered with the polishing liquid.

In order to perform polishing (such as CMP) with the surface state of the polishing cloth always being the same, a conditioning step of the polishing cloth may be performed before polishing. For example, the polishing cloth can be conditioned with a liquid containing at least water, using a dresser with diamond particles attached. Subsequently, after performing the polishing method according to the present embodiment, a substrate cleaning step may be further performed. The substrate after polishing may be thoroughly washed in running water, and then water droplets adhering to the substrate may be removed using a spin-dryer or the like, followed by drying. Alternatively, after performing a known cleaning method (for example, a method of removing adhering substances on the substrate by pressing a rotating polyurethane brush against the substrate with a constant pressure while flowing a commercially available cleaning liquid over the substrate surface), drying may be performed.

The method for manufacturing a part according to the present embodiment includes a part manufacturing step of obtaining a part using a member to be polished (a member to be polished containing a carbon material and/or a metal material) that has been polished by the polishing method according to the present embodiment. The member to be polished (a member to be polished containing a carbon material) that has been polished by the polishing method according to the present embodiment may be used as a hard mask. The part according to the present embodiment is a part obtained by the method for manufacturing a part according to the present embodiment. The part according to the present embodiment is not particularly limited, but may be an electronic part (for example, a semiconductor part such as a semiconductor package), may be a wafer (for example, a semiconductor wafer), and may be a chip (for example, a semiconductor chip). As one aspect of the method for manufacturing a part according to the present embodiment, in the method for manufacturing an electronic part according to the present embodiment, an electronic part is obtained using a member to be polished that has been polished by the polishing method according to the present embodiment. As one aspect of the method for manufacturing a part according to the present embodiment, in the method for manufacturing a semiconductor part according to the present embodiment, a semiconductor part (for example, a semiconductor package) is obtained using a member to be polished that has been polished by the polishing method according to the present embodiment. The method for manufacturing a part according to the present embodiment may include, before the part manufacturing step, a polishing step of polishing the member to be polished by the polishing method according to the present embodiment.

The method for manufacturing a part according to the present embodiment may include, as one aspect of the part manufacturing step, a singulation step of singulating a member to be polished (a member to be polished containing a carbon material and/or a metal material) that has been polished by the polishing method according to the present embodiment. The singulation step may be, for example, a step of obtaining a chip (for example, a semiconductor chip) by dicing a wafer (for example, a semiconductor wafer) that has been polished by the polishing method according to the present embodiment. As one aspect of the method for manufacturing a part according to the present embodiment, the method for manufacturing an electronic part according to the present embodiment may include a step of obtaining an electronic part (for example, a semiconductor part) by singulating a member to be polished that has been polished by the polishing method according to the present embodiment. As one aspect of the method for manufacturing a part according to the present embodiment, the method for manufacturing a semiconductor part according to the present embodiment may include a step of obtaining a semiconductor part (for example, a semiconductor package) by singulating a member to be polished that has been polished by the polishing method according to the present embodiment.

The method for manufacturing a part according to the present embodiment may include, as one aspect of the part manufacturing step, a connection step of connecting (for example, electrically connecting) a member to be polished (a member to be polished containing a carbon material and/or a metal material) that has been polished by the polishing method according to the present embodiment and another member to be connected. The member to be connected that is connected to the member to be polished by the polishing method according to the present embodiment is not particularly limited, and may be a member to be polished by the polishing method according to the present embodiment, or may be a member to be connected different from the member to be polished by the polishing method according to the present embodiment. In the connection step, the member to be polished and the member to be connected may be directly connected (connected in a state where the member to be polished and the member to be connected are in contact), or the member to be polished and the member to be connected may be connected via another member (such as a conductive member). The connection step can be performed before the singulation step, after the singulation step, or before and after the singulation step.

The connection step may be a step of connecting the polished surface of the member to be polished by the polishing method according to the present embodiment and the member to be connected, or may be a step of connecting the connection surface of the member to be polished by the polishing method according to the present embodiment and the connection surface of the member to be connected. The connection surface of the member to be polished may be the polished surface polished by the polishing method according to the present embodiment. By the connection step, a connected body including the member to be polished and the member to be connected can be obtained. In the connection step, when the connection surface of the member to be polished has a metal part, the member to be connected may be brought into contact with the metal part. In the connection step, when the connection surface of the member to be polished has a metal part and the connection surface of the member to be connected has a metal part, the metal parts may be brought into contact with each other. The metal part may include copper.

A device (for example, an electronic device such as a semiconductor device) according to the present embodiment includes at least one selected from the group consisting of a member to be polished (a member to be polished containing a carbon material and/or a metal material) that has been polished by the polishing method according to the present embodiment, and a part according to the present embodiment.

### EXAMPLES

Hereinafter, the present disclosure will be described in more detail with reference to examples, but the present disclosure is not limited to these examples as long as it does not depart from the technical idea of the present disclosure.

### <Preparation of CMP Polishing Liquid>

### Example 1

A CMP polishing liquid was obtained by mixing iron(III) nitrate nonahydrate and glycine in deionized water. Based on the total mass of the CMP polishing liquid, the content of iron(III) nitrate nonahydrate was 0.08 mass % (content of iron ions: 0.011 mass %), and the content of glycine was 3.00 mass %.

### Example 2

A CMP polishing liquid was obtained by mixing iron(III) nitrate nonahydrate, glycine, and a 30 mass % aqueous solution of hydrogen peroxide in deionized water. Based on the total mass of the CMP polishing liquid, the content of iron(III) nitrate nonahydrate was 0.08 mass % (content of iron ions: 0.011 mass %), the content of glycine was 3.00 mass %, and the content of hydrogen peroxide (content of hydrogen peroxide itself) was 4.00 mass %.

### Example 3

A CMP polishing liquid was obtained in the same manner as in Example 1, except that the content of iron(III) nitrate nonahydrate was changed to 0.04 mass % (content of iron ions: 0.055 mass %).

### Example 4

A CMP polishing liquid was obtained in the same manner as in Example 1, except that the content of iron(III) nitrate nonahydrate was changed to 0.01 mass % (content of iron ions: 0.0014 mass %).

### Example 5

A CMP polishing liquid was obtained by mixing iron(III) nitrate nonahydrate, glycine, and 3-methoxy-3-methyl-1-butanol (MMB) in deionized water. Based on the total mass of the CMP polishing liquid, the content of iron(III) nitrate nonahydrate was 0.08 mass % (content of iron ions: 0.011 mass %), the content of MMB was 3.00 mass %, and the content of glycine was 3.00 mass %.

### Example 6

A CMP polishing liquid was obtained in the same manner as in Example 1, except that the content of iron(III) nitrate nonahydrate was changed to 0.80 mass % (content of iron ions: 0.11 mass %), and the content of glycine was changed to 0.30 mass %.

### Example 7

A CMP polishing liquid was obtained by mixing iron(II) acetate and glycine in deionized water. Based on the total mass of the CMP polishing liquid, the content of iron(II) acetate was 0.03 mass % (content of iron ions: 0.011 mass %), and the content of glycine was 0.18 mass %.

### Example 8

A CMP polishing liquid was obtained by mixing iron(III) nitrate nonahydrate and β-alanine in deionized water. Based on the total mass of the CMP polishing liquid, the content of iron(III) nitrate nonahydrate was 0.08 mass % (content of iron ions: 0.011 mass %), and the content of β-alanine was 0.30 mass %.

### Example 9

A CMP polishing liquid was obtained in the same manner as in Example 1, except that glycine was not used.

### Comparative Example 1

A CMP polishing liquid was obtained by mixing glycine, a 30 mass % aqueous solution of hydrogen peroxide, and MMB in deionized water. Based on the total mass of the CMP polishing liquid, the content of glycine was 3.00 mass %, the content of hydrogen peroxide (content of hydrogen peroxide itself) was 4.00 mass %, and the content of MMB was 3.00 mass %.

### Example 10

Iron(III) nitrate nonahydrate and abrasive grains (colloidal silica, trade name: PL-10H, average particle size: 179 nm, old Mohs hardness: 6 to 7) were mixed in deionized water. Then, glycine, a 30 mass % aqueous solution of hydrogen peroxide, and MMB were added to obtain a CMP polishing liquid. Based on the total mass of the CMP polishing liquid, the content of abrasive grains (content of silica, which is the solid content) was 1 mass %, the content of iron(III) nitrate nonahydrate was 0.08 mass % (content of iron ions: 0.011 mass %), the content of glycine was 3.00 mass %, the content of hydrogen peroxide (content of hydrogen peroxide itself) was 4.00 mass %, and the content of MMB was 3.00 mass %.

### Example 11

A CMP polishing liquid was obtained in the same manner as in Example 10, except that the content of abrasive grains was changed to 5 mass %.

### Example 12

A CMP polishing liquid was obtained in the same manner as in Example 10, except that the content of iron(III) nitrate nonahydrate was changed to 0.04 mass % (content of iron ions: 0.0055 mass %).

### Example 13

A CMP polishing liquid was obtained in the same manner as in Example 10, except that the content of iron(III) nitrate nonahydrate was changed to 0.12 mass % (content of iron ions: 0.017 mass %).

### Example 14

A CMP polishing liquid was obtained in the same manner as in Example 10, except that iron(III)nitrate nonahydrate was changed to iron(II) acetate, and the content of iron(II) acetate was 0.03 mass % (content of iron ions: 0.011 mass %).

### Example 15

A CMP polishing liquid was obtained in the same manner as in Example 10, except that the content of glycine was changed to 0.30 mass %.

### Example 16

A CMP polishing liquid was obtained in the same manner as in Example 10, except that the content of glycine was changed to 0.60 mass %.

### Example 17

A CMP polishing liquid was obtained in the same manner as in Example 10, except that the content of glycine was changed to 1.50 mass %.

### Example 18

A CMP polishing liquid was obtained in the same manner as in Example 10, except that glycine was changed to β-alanine, and the content of β-alanine was 0.30 mass %.

### Example 19

A CMP polishing liquid was obtained in the same manner as in Example 10, except that glycine was changed to β-alanine, and the content of β-alanine was 4.00 mass %.

### Example 20

A CMP polishing liquid was obtained in the same manner as in Example 10, except that the abrasive grains were changed to spherical silica fine particles (trade name: Seahostar KE-W30, average particle size: 290 nm, old Mohs hardness: 6 to 7).

### Example 21

A CMP polishing liquid was obtained in the same manner as in Example 10, except that the abrasive grains were changed to spherical silica fine particles (trade name: Seahostar IX-3-SH-W50, average particle size: 540 nm, old Mohs hardness: 6 to 7).

### Example 22

A CMP polishing liquid was obtained in the same manner as in Example 10, except that the abrasive grains were changed to colloidal silica (trade name: ST-AK-YL, average particle size: 60 inn, old Mohs hardness: 6 to 7).

### Comparative Example 2

A CMP polishing liquid was obtained in the same manner as in Example 10, except that iron(III) nitrate nonahydrate was changed to a 0.1 mol/aqueous solution of zinc acetate, and the content of zinc acetate (content of zinc acetate itself) was 0.04 mass % (content of zinc ions: 0.013 mass %).

### <Measurement of Average Particle Size of Abrasive Grains>

As a result of measuring the average particle size of the abrasive grains in the above-mentioned CMP polishing liquid using a COUITER N4SD manufactured by COULTER Electronics, there was no change in the average particle size of the abrasive grains before and after the preparation of the polishing liquid in all Examples.

<Measurement of pH>

The pH of the above-mentioned CMP polishing liquid was measured using a product with the trade name “Model (F-51)” manufactured by HORIBA, Ltd. Specifically, after performing a three-point calibration of the pH meter using a phthalate pH standard solution (pH: 4.01), a neutral phosphate pH standard solution (pH: 6.86), and a borate pH standard solution (pH: 9.18) as calibration solutions, the electrode of the pH meter was placed in the CMP polishing liquid, and the value after stabilization for 2 minutes or more was measured. The liquid temperature of the calibration solutions and the CMP polishing liquid was 25° C. The results are shown in Tables I and 2.

### <Measurement of Polishing Rate>

As an evaluation test wafer, a 12-inch diameter substrate having a 10 μm thick polyimide resin layer (manufactured by HD MicroSystems, HD7000 series) on a silicon substrate was prepared. In addition, as an evaluation test wafer, a 12-inch diameter substrate having a 1.5 μm thick copper layer on a silicon substrate was prepared. Using the above-mentioned CMP polishing liquid, the polyimide resin layer and the copper layer were respectively polished (CMP) under the following polishing conditions. The difference in the thickness of the polyimide resin layer before and after polishing was measured using an optical film thickness meter (manufactured by Filmetrics, Inc., F54-UV), and the difference in the thickness of the copper layer before and after polishing was measured using a metal film thickness meter (manufactured by Napson Corporation, WS-3000), and the polishing rates of the polyimide resin and copper were calculated based on the difference in the thickness of each layer and the polishing time. The results are shown in Tables I and 2. In addition, using the CMP polishing liquid of Example 1, the polishing rates of a 9 μm thick polyimide resin (manufactured by H) MicroSystems, HD4000 series), a 9 μm thick polyimide resin (manufactured by HD MicroSystems, HD3000 series), a 10 pin thick polybenzoxazole resin (manufactured by HD MicroSystems, HD8000 series), and a 4.8 μm thick polybenzoxazole resin (manufactured by Sumitomo Bakelite Co., Ltd., CRC8903) were measured in the same manner as for the polyimide resin (ID7000 series). The polishing rate of the polyimide resin (HD4000 series) was 449 nm/min, the polishing rate of the polyimide resin (HD3000 series) was 679 nm/min, the polishing rate of the polybenzoxazole resin (HD8000 series) was 1347 nm/min, and the polishing rate of the polybenzoxazole resin (CRC8903) was 1117 nm/min.

### [Polishing Conditions]

Polishing apparatus: manufactured by Applied Materials, Inc., trade name “Reflexion LK”
Polishing pad: IK425011 (manufactured by DuPont)
Polishing pressure: 4 psi
Platen rotation speed: 87 rpm
Head rotation speed: 93 rpm
CMP polishing liquid supply rate: 300 mL/min
Polishing time: 1 minute

TABLE 1

| | | | | | | | | | | | Compar- |
|---|---|---|---|---|---|---|---|---|---|---|---|
| | | | | | | | | | | | ative |
| | | Exam- | Exam- | Exam- | Exam- | Exam- | Exam- | Exam- | Exam- | Exam- | Exam- |
| | | ple 1 | ple 2 | ple 3 | ple 4 | ple 5 | ple 6 | ple 7 | ple 8 | ple 9 | ple 1 |
| Iron ions | Derived from | 0.011 | 0.011 | 0.0055 | 0.0014 | 0.011 | 0.11 | — | 0.011 | 0.011 | — |
| (mass %) | iron nitrate | | | | | | | | | | |
| | Derived from | — | — | — | — | — | — | 0.011 | — | — | — |
| | iron acetate | | | | | | | | | | |
| Organic acid | Glycine | 3.00 | 3.00 | 3.00 | 3.00 | 3.00 | 0.30 | 0.18 | — | — | 3.00 |
| component | β-alanine | — | — | — | — | — | — | — | 0.30 | — | — |
| (mass %) | | | | | | | | | | | |
| Oxidizing agent | Hydrogen | — | 4.00 | — | — | — | — | — | — | — | 4.00 |
| (mass %) | peroxide | | | | | | | | | | |
| Organic solvent | MMB | — | — | — | — | 3.00 | — | — | — | — | 3.00 |
| (mass %) | | | | | | | | | | | |
| pH | | 4.31 | 4.24 | 4.62 | 5.19 | 4.31 | 2.51 | 4.19 | 4.33 | 2.86 | 6.03 |
| Polishing rate | Polyimide resin | 405 | 415 | 269 | 105 | 342 | 314 | 337 | 428 | 291 | 1 |
| (nm/min) | Copper | 12 | 880 | 18 | 11 | 17 | 25 | 6 | 7 | 28 | 774 |

TABLE 2

| | | Example 10 | Example 11 | Example 12 | Example 13 | Example 14 | Example 15 | Example 16 |
|---|---|---|---|---|---|---|---|---|
| Abrasive | PL-10H | 1 | 5 | 1 | 1 | 1 | 1 | 1 |
| grains | KE-W30 | — | — | — | — | — | — | — |
| (mass %) | IX-3-SH-W50 | — | — | — | — | — | — | — |
| | ST-AK-YL-A | — | — | — | — | — | — | — |
| Iron ions | Derived from | 0.011 | 0.011 | 0.0055 | 0.017 | — | 0.011 | 0.011 |
| (mass %) | iron nitrate | | | | | | | |
| | Derived from | — | — | — | — | 0.011 | — | — |
| | iron acetate | | | | | | | |
| Metal ions other than | Derived from | — | — | — | — | — | — | — |
| iron ions (mass %) | zinc acetate | | | | | | | |
| Organic acid | Glycine | 3.00 | 3.00 | 3.00 | 3.00 | 3.00 | 0.30 | 0.60 |
| component | β-alanine | — | — | — | — | — | — | — |
| (mass %) | | | | | | | | |
| Oxidizing agent | Hydrogen | 4.00 | 4.00 | 4.00 | 4.00 | 4.00 | 4.00 | 4.00 |
| (mass %) | peroxide | | | | | | | |
| Organic solvent | MMB | 3.00 | 3.00 | 3.00 | 3.00 | 3.00 | 3.00 | 3.00 |
| (mass %) | | | | | | | | |
| pH | | 4.29 | 4.28 | 4.64 | 4.10 | — | 3.19 | 3.52 |
| Polishing rate | Polyimide resin | 353 | 270 | 235 | 463 | 261 | 381 | 373 |
| (nm/min) | Copper | 1745 | 1967 | 1899 | 1916 | — | 311 | 554 |

| | | | | | | | | Comparative |
|---|---|---|---|---|---|---|---|---|
| | | Example 17 | Example 18 | Example 19 | Example 20 | Example 21 | Example 22 | Example 2 |
| Abrasive | PL-10H | 1 | 1 | — | — | — | — | 1 |
| grains | KE-W30 | — | — | 1 | — | — | — | — |
| (mass %) | IX-3-SH-W50 | — | — | — | 1 | — | — | — |
| | ST-AK-YL-A | — | — | — | — | 1 | — | — |
| Iron ions | Derived from | 0.011 | 0.011 | 0.011 | 0.011 | 0.011 | 0.011 | — |
| (mass %) | iron nitrate | | | | | | | |
| | Derived from | — | — | — | — | — | — | — |
| | iron acetate | | | | | | | |
| Metal ions other than | Derived from | — | — | — | — | — | — | 0.013 |
| iron ions (mass %) | zinc acetate | | | | | | | |
| Organic acid | Glycine | 1.50 | — | — | 3.00 | 3.00 | 3.00 | 3.00 |
| component | β-alanine | — | 0.30 | 4.00 | — | — | — | — |
| (mass %) | | | | | | | | |
| Oxidizing agent | Hydrogen | 4.00 | 4.00 | 4.00 | 4.00 | 4.00 | 4.00 | 4.00 |
| (mass %) | peroxide | | | | | | | |
| Organic solvent | MMB | 3.00 | 3.00 | 3.00 | 3.00 | 3.00 | 3.00 | 3.00 |
| (mass %) | | | | | | | | |
| pH | | 3.95 | 4.26 | 5.54 | — | — | — | — |
| Polishing rate | Polyimide resin | 382 | 231 | 349 | 360 | 369 | 370 | 5 |
| (nm/min) | Copper | 1158 | 67 | 185 | — | — | — | — |

1. A CMP polishing liquid for polishing a member to be polished comprising a carbon material, wherein a content of abrasive grains is from 0 to 5 mass %,
Wherein the CMP polishing liquid comprises iron ions.

2. The CMP polishing liquid according to claim 1, wherein a content of the iron ions is from 0.001 to 0.2 mass %.

3. The CMP polishing liquid according to claim 1, wherein the content of the abrasive grains is from 0 to 0.01 mass %.

4. The CMP polishing liquid according to claim 1, wherein the abrasive grains comprise particles having an old Mohs hardness of less than 8.

5. The CMP polishing liquid according to claim 1, wherein the abrasive grains comprise silica particles.

6. The CMP polishing liquid according to claim 1, wherein a mass ratio of the content of the abrasive grains to the content of the iron ions is from 0 to 500.

7. The CMP polishing liquid according to claim 1, further comprising an oxidizing agent.

8. The CMP polishing liquid according to claim 7, wherein the oxidizing agent comprises a peroxide.

9. The CMP polishing liquid according to claim 1, further comprising an organic acid component.

10. The CMP polishing liquid according to claim 9, wherein the organic acid component comprises an amino acid component.

11. The CMP polishing liquid according to claim 9, wherein a content of the organic acid component is from 0.1 to 5 mass %.

12. The CMP polishing liquid according to claim 1, further comprising an organic solvent.

13. The CMP polishing liquid according to claim 12, wherein the organic solvent comprises 3-methoxy-3-methyl-1-butanol.

14. The CMP polishing liquid according to claim 1, wherein the pH is from 1.0 to 7.0.

15. The CMP polishing liquid according to claim 1, wherein the carbon material comprises a polyimide resin.

16. The CMP polishing liquid according to claim 1, wherein the member to be polished further comprises a metal material.

17. The CMP polishing liquid according to claim 16, wherein the metal material comprises at least one selected from the group consisting of copper, copper alloy, copper oxide, and copper alloy oxide.

18. A polishing method, comprising a step of polishing a member to be polished comprising a carbon material using the CMP polishing liquid according tom claim 1.

19. A method for manufacturing a semiconductor device, comprising a step of obtaining a semiconductor device using a member to be polished that has been polished by the polishing method according to claim 18.
